(19) United States
(12) Patent Application Publication
(10) Pub. No.: US 2005/0053246 A1
(43) Pub. Date: Mar. 10, 2005

(54) Automatic sound field correction apparatus and computer program therefor

(75) Inventor: Hajime Yoshino, Tokorozawa-shi (JP)

Correspondence Address: MORGAN LEWIS & BOCKIUS LLP, 1111 PENNSYLVANIA AVENUE NW, WASHINGTON, DC, 20004, US

(73) Assignee: PIONEER CORPORATION

(21) Appl. No.: 10/927,527

(22) Filed: Aug. 27, 2004

(30) Foreign Application Priority Data
Aug. 27, 2003 (JP) P2003-209056

(51) Int. Cl. H04R 5/00; H04R 3/00; H03G 5/00

(52) U.S. Cl. 381/96; 381/103

(57) ABSTRACT

An automatic sound field correction apparatus processes multi-channel audio signals on respective signal transmission lines and reproduces them via a plurality of speakers. When adjusting frequency characteristics of the signal transmission lines, a measurement signal is supplied to the signal transmission lines and measurement signal sounds are emitted from the respective speakers. Then, the measurement signal sounds during a direct sound period are detected as detection signals by a detection device such as a microphone. Equalizer gain values are set appropriately based on the detection signals, thereby adjusting the frequency characteristics of the signal transmission lines. During the direct sound period in which the measurement signal sounds are detected, since the measurement signal sounds do not contain a reverberant component, the frequency characteristics of the signal transmission lines can be adjusted mainly using the direct sounds. Thus, it makes such corrections that will give desired frequency characteristics mainly to direct sounds without influence from reverberant sounds.

### BACKGROUND OF THE INVENTION

1. Field of the Invention

The present invention relates to an automatic sound field correction system and sound field correction method which automatically correct sound-field characteristics of an audio system equipped with a plurality of speakers.

2. Description of the Related Art

Audio systems which are equipped with a plurality of speakers and provide high-quality audio space are required to automatically create an appropriate audio space with a sense of presence. That is, they are required to correct sound-field characteristics automatically because it is extremely difficult to adjust phase characteristics, frequency characteristics, sound pressure levels, etc. of sounds reproduced by a plurality of speakers even if a listener himself/herself operates an audio system to obtain an appropriate audio space.

Known automatic sound field correction systems of this type include a system disclosed in US2002-159605A (which is incorporated herein by reference, and which corresponds with JP2002-330499A and EP1253805A2). In relation to signal transmission lines which correspond to a plurality of channels, this system collects test signals outputted from speakers, analyzes their frequency characteristics, sets coefficients of equalizers installed in the respective signal transmission lines, and thereby adjusts the signal transmission lines to desired frequency characteristics. As the test signals, pink noise or the like is used, for example.

The conventional automatic sound field correction systems such as the one described above do not discuss when to capture the test signals and use them in analyzing the frequency characteristics after the test signals outputted from the speakers reach an analyzer. Generally, test signals are captured some time after the test signals reach the analyzer, i.e., the test signals are captured when reverberant sounds are echoing sufficiently to analyze frequency characteristics.

However, if frequency characteristics of signal transmission lines are analyzed with reverberant components of test signals included, the frequency characteristics of signal transmission lines are adjusted during reproduction of a sound source signal in such a way that target frequency characteristics are obtained after reverberant sounds echo sufficiently. Consequently, the frequency characteristics of signal transmission lines are adjusted in such a way that direct sounds from the speakers which greatly affect auditory sound quality, including a sense of presence and sense of orientation, do not attain target frequency characteristics. Also, if reverberation characteristics differ among channels, direct sounds from the speakers seem differently among the channels when a sound source signal is reproduced, which is a problem.

### SUMMARY OF THE INVENTION

The above are examples of problems to be solved by the present invention. The present invention has an object to provide an automatic sound field correction system capable of making such corrections that will give desired frequency characteristics mainly to direct sounds without influence from reverberant sounds as well as to provide a computer program therefor.

According to a first aspect of the present invention, there is provided an automatic sound field correction apparatus which processes a plurality of audio signals on respective signal transmission lines and outputs the audio signals to respective speakers, and which comprises equalizers which adjust frequency characteristics of the audio signals on the signal transmission lines; a measurement signal supply device which supplies a measurement signal to the signal transmission lines; a detection device which outputs measurement signal sounds emitted from the speakers, as detection signals during a direct sound period; and a gain determination device which determines equalizer gain values for use by the equalizers to adjust the frequency characteristics, based on the detection signals, and supplies them to the equalizers, wherein the direct sound period is a period during which the measurement signal sounds reaching the collection device do not contain a reverberant component.

According to another aspect of the present invention, there is provided a computer program for making a computer function as an automatic sound field correction apparatus which processes a plurality of audio signals on respective signal transmission lines and outputs the audio signals to respective speakers, wherein the automatic sound field correction apparatus comprises equalizers which adjust frequency characteristics of the audio signals on the signal transmission lines; a measurement signal supply device which supplies a measurement signal to the signal transmission lines; a detection device which outputs measurement signal sounds emitted from the speakers, as detection signals during a direct sound period; and a gain determination device which determines equalizer gain values for use by the equalizers to adjust the frequency characteristics, based on the detection signals, and supplies them to the equalizers, wherein the direct sound period is a period during which the measurement signal sounds reaching the collection device do not contain a reverberant component.

### BRIEF DESCRIPTION OF THE DRAWINGS

FIG. 1 is a block diagram showing a configuration of an audio system equipped with an automatic sound field correction apparatus according to an example of the present invention;

FIG. 2 is a block diagram showing an internal configuration of a signal processing circuit shown in FIG. 1;

FIG. 3 is a block diagram showing a configuration of a signal processing unit shown in FIG. 2;

FIG. 4 is a block diagram showing a configuration of a coefficient computing unit shown in FIG. 2;

FIGS. 5A, 5B and 5C are block diagrams showing configurations of a frequency characteristics correction unit, channel-to-channel level correction unit, and delay characteristics correction unit, respectively;

FIG. 6 is a diagram showing an exemplary arrangement of speakers in a sound field environment;

FIG. 7 is a flowchart showing a main routine of an automatic sound field correction process;

FIG. 8 is a diagram schematically showing a configuration for frequency characteristics correction;

FIG. 9 is a graph showing changes in sound pressure level of measurement signal sounds for automatic sound field correction;

FIG. 10 is a flowchart showing a frequency characteristics correction process;

FIG. 11 is a flowchart showing a channel-to-channel level correction process; and

FIG. 12 is a flowchart showing a delay characteristics correction process.

### DETAILED DESCRIPTION OF THE PREFERRED EMBODIMENTS

From the first aspect, the present invention is an automatic sound field correction apparatus which processes a plurality of audio signals on respective signal transmission lines and outputs the audio signals to respective speakers, and which comprises equalizers which adjust frequency characteristics of the audio signals on the signal transmission lines; a measurement signal supply device which supplies a measurement signal to the signal transmission lines; a detection device which outputs measurement signal sounds emitted from the speakers, as detection signals during a direct sound period; and a gain determination device which determines equalizer gain values for use by the equalizers to adjust the frequency characteristics, based on the detection signals, and supplies them to the equalizers, wherein the direct sound period is a period during which the measurement signal sounds reaching the detection device do not contain a reverberant component.

The automatic sound field correction apparatus processes the multi-channel audio signals on the respective signal transmission lines and reproduces them via the plurality of speakers. When adjusting the frequency characteristics of the signal transmission lines, the measurement signal is supplied to the signal transmission lines and the measurement signal sounds are emitted from the respective speakers. Then, the measurement signal sounds during the direct sound period are detected as detection signals by the detection device such as a microphone. The equalizer gain values are adjusted appropriately based on the detection signals, thereby adjusting the frequency characteristics of the signal transmission lines. During the direct sound period in which the measurement signal sounds are detected, since the measurement signal sounds do not contain a reverberant component, the frequency characteristics of the signal transmission lines can be adjusted mainly using the direct sounds.

According to one embodiment of the automatic sound field correction apparatus, the direct sound period may be a period during which the measurement signal sounds reaching the detection device contain a direct sound component and early reflection component. A sound source signal is reproduced after the frequency characteristics of the signal transmission lines are adjusted. In a normal environment, a user listens to the direct sound component and early reflection component of the sound source signal reproduced by speakers or the like. Thus, it is useful to take the early reflection component into consideration when adjusting the frequency characteristics.

According to a preferred example, the direct sound period falls within a predetermined time range, for example, 20 to 40 msec, counting from a time point at which a measurement signal sound is first detected by the collection device.

Another embodiment of the automatic sound field correction apparatus comprises a delay measuring device which measures signal delay times on the respective signal transmission lines, wherein the detection device determines the direct sound period based on the time point at which the measurement signal sounds are emitted from the speakers, the signal delay times on the signal transmission lines, and the predetermined time range. This makes it possible to detect the measurement signal sounds accurately during the direct sound period based on the measured signal delay times on the respective signal transmission lines.

From another aspect, the present invention is a computer program for making a computer function as an automatic sound field correction apparatus which processes a plurality of audio signals on respective signal transmission lines and outputs the audio signals to respective speakers, wherein the automatic sound field correction apparatus comprises equalizers which adjust frequency characteristics of the audio signals on the signal transmission lines; a measurement signal supply device which supplies a measurement signal to the signal transmission lines; a detection device which outputs measurement signal sounds emitted from the speakers, as detection signals during a direct sound period; and a gain determination device which determines equalizer gain values for use by the equalizers to adjust the frequency characteristics, based on the detection signals, and supplies them to the equalizers, wherein the direct sound period is a period during which the measurement signal sounds reaching the detection device do not contain a reverberant component.

The above program, when loaded onto a computer and executed, can make the computer function as the automatic sound field correction apparatus.

### EXAMPLES

1. System Configuration

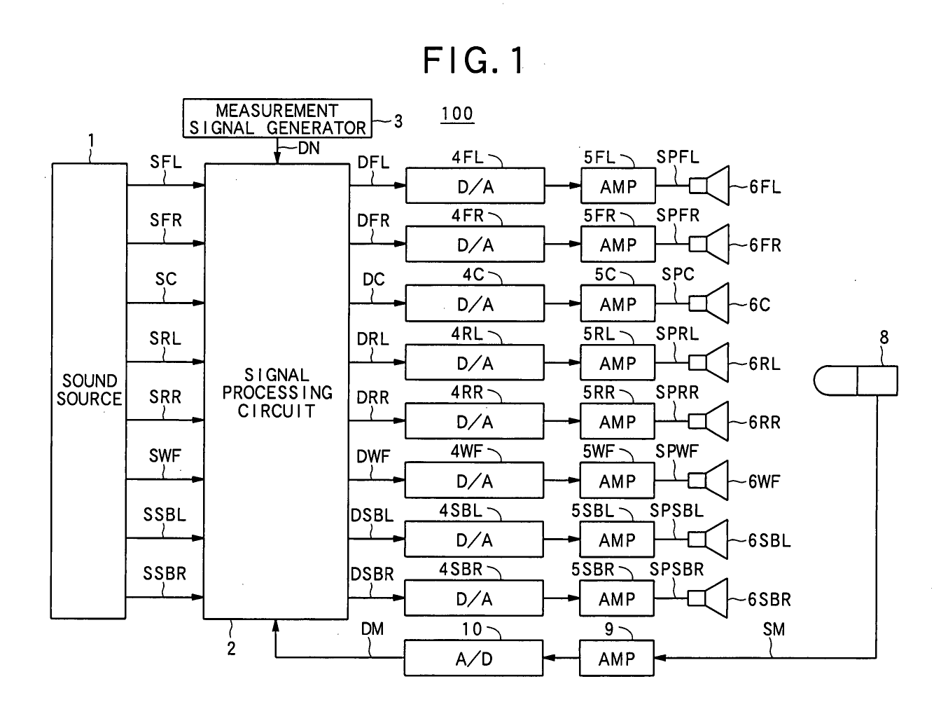

An example of the automatic sound field correction apparatus according to the present invention will be described below with reference to the drawings. FIG. 1 is a block diagram showing a configuration of an audio system equipped with the automatic sound field correction apparatus according to this example.

Referring to FIG. 1, the audio system 100 is equipped with a signal processing circuit 2 and measurement signal generator 3. The signal processing circuit 2 is fed digital audio signals S_{FL}, S_{FR}, S_{C}, S_{RL}, S_{RR}, S_{WF}, S_{SBL}, and S_{SBR} from a sound source 1 such as a CD (Compact Disc) player or DVD (Digital Video Disc or Digital Versatile Disc) via multi-channel signal transmission lines.

Incidentally, the audio system 100 includes multi-channel signal transmission lines and individual channels may be referred to as an “FL channel,” “FR channel,” etc. hereinafter. Also, when referring to all the channels in describing signals and components, subscripts may be omitted from reference characters. On the other hand, when referring to signals and components of individual channels, subscripts which identify the channels are attached to the reference characters. For example, “digital audio signals S” mean the digital audio signals S_{FL} to S_{SBR} on all the channels while a “digital audio signal SFL” means the digital audio signal on the FL channel alone.

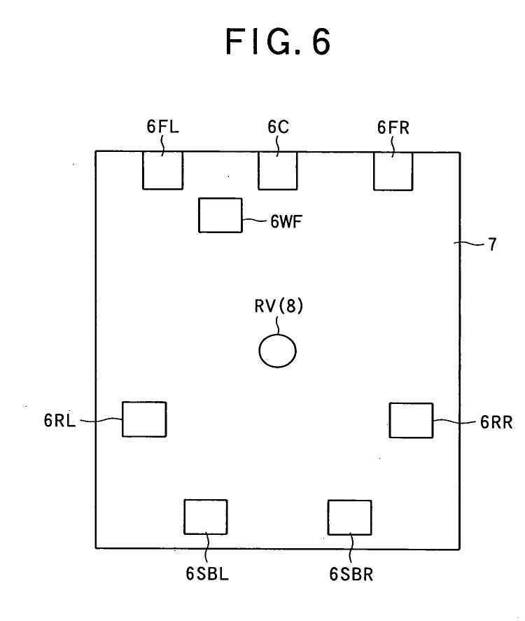

The audio system 100 further comprises D/A converters 4_{FL} to 4_{SBR} which convert digital outputs D_{FL} to D_{SBR} processed on a channel-by-channel basis by the signal processing circuit 2 into analog signals and amplifiers 5_{FL} to 5_{SBR} which amplify the analog audio signals outputted from the D/A converters 4_{FL} to 4_{SBR}. Resulting analog audio signals SP_{FL} to SP_{SBR} are supplied to, and reproduced by, multi-channel speakers 6_{FL} to 6_{SBR} placed in a listening room 7 or the like illustrated in FIG. 6.

Also, the audio system 100 comprises a microphone 8 which collects reproduced sounds at a listening position RV, an amplifier 9 which amplifies a microphone signal SM outputted from the microphone 8, and an A/D converter 10 which converts amplifier 9 output into microphone data DM and supplies the microphone data DM to the signal processing circuit 2.

The audio system 100 provides an audio space with a sense of presence to a listener at the listening position RV using full-range speakers 6_{FL}, 6_{FR}, 6_{C}, 6_{RL}, and 6_{RR} with frequency characteristics covering an entire audio frequency band, a speaker 6_{WF} which is dedicated to low-frequency reproduction and has frequency characteristics for reproducing only deep bass, and surround speakers 6_{SBL} and 6_{SBR} placed behind the listener.

Regarding arrangement of the speakers, as shown in FIG. 6, for example, the listener places two front speakers 6_{FL} and 6_{FR} for left and right channels (left front speaker and right front speaker) and a center speaker 6_{C} in front of the listening position RV according to personal preference. Also, the listener places two rear speakers 6_{RL} and 6_{RR} for left and right channels (left rear speaker and right rear speaker) as well as two surround speakers 6_{SBL} and 6_{SBR} for left and right channels behind the listening position RV. Besides, a sub-woofer 6_{WF} dedicated to low-frequency reproduction is placed at any desired location. An automatic sound field correction system attached to the audio system 100 supplies analog audio signals SP_{FL} to SP_{SBR} to the eight speakers 6_{FL} to 6_{SBR} after correcting their frequency characteristics, channel-by-channel signal levels, and signal delay characteristics so that the speakers 6_{FL} to 6_{SBR} will reproduce the audio signals to create an audio space with a sense of presence.

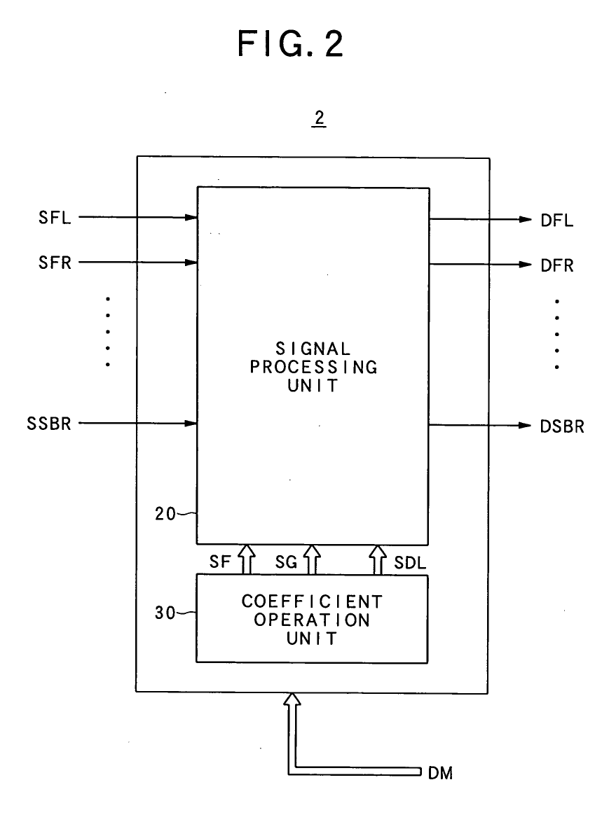

The signal processing circuit 2 consists of a digital signal processor (DSP) and the like. As shown in FIG. 2, it is roughly divided into a signal processing unit 20 and coefficient computing unit 30. The signal processing unit 20 receives multi-channel digital audio signals from a sound source 1 for playing back CD, DVD, and other music sources, corrects their frequency characteristics, signal levels, and delay characteristics on a channel-by-channel basis, and outputs digital output signals D_{FL to D}_{SBR}. The coefficient computing unit 30 receives signals collected by the microphone 8 as digital microphone data DM, generates coefficient signals SF₁ to SF₈, SG₁ to SG₈, and SDL₁ to SDL₈ for frequency characteristics correction, level correction, and delay characteristics correction, respectively, and supplies them to the signal processing unit 20. As the signal processing unit 20 makes appropriate frequency characteristics corrections, level corrections, and delay characteristics corrections based on the microphone data DM from the microphone 8, optimum signals are output from the speakers 6.

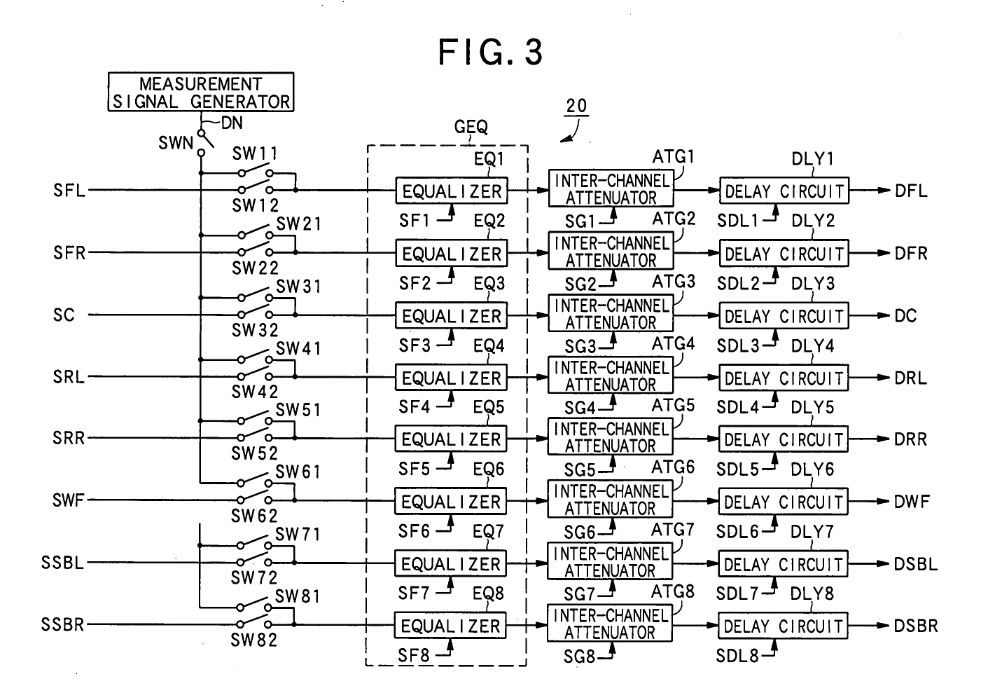

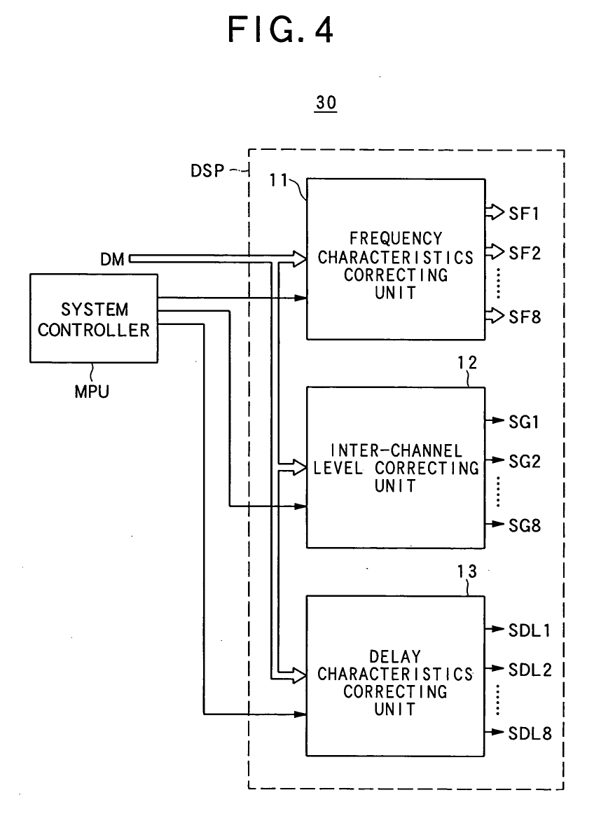

As shown in FIG. 3, the signal processing unit 20 comprises a graphic equalizer GEQ, channel-to-channel attenuators ATG₁ to ATG₈, and delay circuits DLY₁ to DLY₈. On the other hand, the coefficient computing unit 30 comprises a system controller MPU, frequency characteristics correction unit 11, channel-to-channel level correction unit 12, and delay characteristics correction unit 13 as shown in FIG. 4. The frequency characteristics correction unit 11, channel-to-channel level correction unit 12, and delay characteristics correction unit 13 compose a DSP.

To make an appropriate sound field correction, the frequency characteristics correction unit 11 adjusts frequency characteristics of equalizers EQ₁ to EQ₈ which correspond to individual channels of the graphic equalizer GEQ, the channel-to-channel level correction unit 12 adjusts attenuation factors of the channel-to-channel attenuators ATG₁ to ATG₈, and the delay characteristics correction unit 13 adjusts delay times of the delay circuits DLY₁ to DLY₈.

The channel-specific equalizers EQ₁ to EQ₅, EQ₇, and EQ₈ are designed to make frequency characteristics corrections on a plurality of frequency bands. Specifically, frequency characteristics corrections are made by dividing an audio frequency band into nine frequency bands, for example (center frequencies of the frequency bands are denoted by f1 to f9), and determining an equalizer EQ coefficient for each frequency band. Incidentally, the equalizer EQ₆ is configured to adjust the low frequency characteristics.

The audio system 100 has two operation modes: automatic sound field correction mode and sound source signal reproduction mode. The automatic sound field correction mode is used before reproduction of signals from the sound source 1 to make an automatic sound field correction for an environment in which the audio system 100 is installed. Then, sound signals from a sound source 1 such as CD are reproduced in the sound source signal reproduction mode. The present invention relates mainly to correction processes in the automatic sound field correction mode.

Referring to FIG. 3, the equalizer EQ₁ of the FL channel is connected with a switching element SW₁₂ which turns on and off input of the digital audio signal S_{FL} from the sound source 1 as well as with a switching element SW₁₁ which turns on and off input of the a measurement signal DN from the measurement signal generator 3, where the switching element SW₁₁ is connected to the measurement signal generator 3 via a switching element SW_{N}.

The switching elements SW₁₁, SW₁₂, and SW_{N} are controlled by the system controller MPU constituted of a microprocessor shown in FIG. 4. During reproduction of sound source signals, the switching element SW₁₂ is on (conducting) and the switching elements SW₁₁ and SW_{N} are off (non-conducting). During sound field correction, the switching element SW₁₂ is off (non-conducting) and the switching elements SW₁₁ and SW_{N} are on (conducting).

An output contact of the equalizer EQ₁ is connected with the channel-to-channel attenuator ATG₁ and an output contact of the channel-to-channel attenuator ATG₁ is connected with the delay circuit DLY₁. Output D_{FL} of the delay circuit DLY₁ is supplied to the D/A converter 4_{FL} shown in FIG. 1.

The other channels have same configuration as the FL channel. They are equipped with switching elements SW₂₁ to SW₈₁ which correspond to the switching element SW₁₁ as well as with switching elements SW₂₂ to SW₈₂ which correspond to the switching element SW₁₂. Subsequent to the switching elements SW₂₁ to SW₈₂, the channels are equipped with the equalizers EQ₂ to EQ₈, the channel-to-channel attenuators ATG₂ to ATG₈, and the delay circuits DLY₂ to DLY₈. The outputs D_{FR} to D_{SBR} of the delay circuits DLY₂ to DLY₈ are supplied to the D/A converters 4_{FR} to 4_{SBR}.

Furthermore, the channel-to-channel attenuators ATG₁ to ATG₈ vary attenuation factors within a range not exceeding 0 dB according to the adjustment signals SG₁ to SG₈ from the channel-to-channel level correction unit 12. Also, the delay circuits DLY₁ to DLY₈ of the channels vary the delay times of input signals according to the adjustment signals SDL₁ to SDL₈ from the phase characteristics correction unit 13.

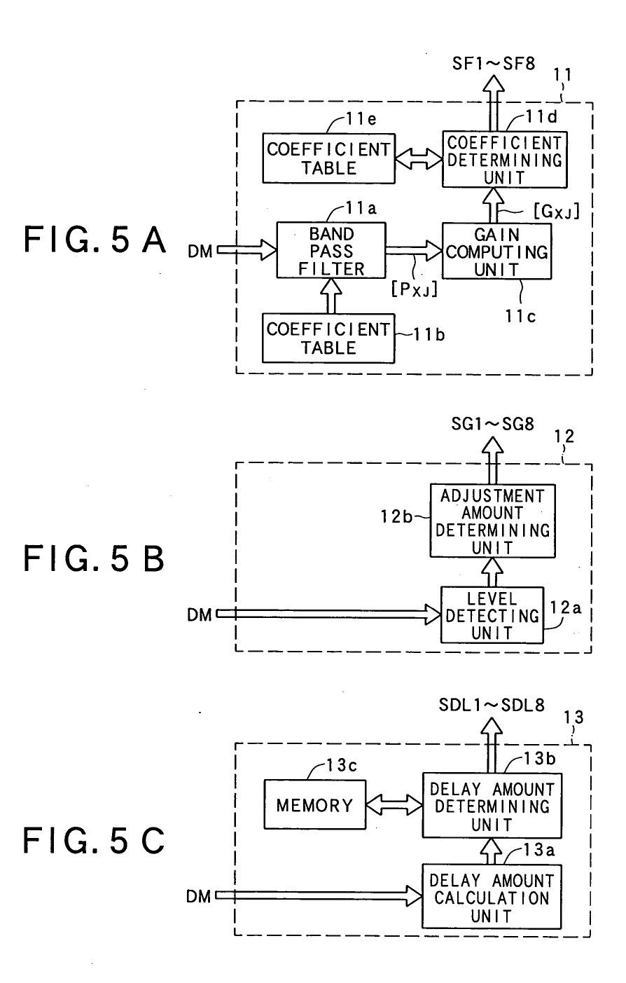

The frequency characteristics correction unit 11 has a function to adjust the frequency characteristics of each channel to obtain desired characteristic. As shown in FIG. 5A, the frequency characteristics correction unit 11 comprises a band pass filter 11a, coefficient table 11b, gain computing unit 11c, coefficient determining unit 11d, and coefficient table 11e.

The band pass filter 11a consists of narrow-band digital filters which are installed in the equalizers EQ₁ to EQ₈ and pass nine frequency bands. It differentiates the microphone data DM received from the A/D converter 10 into nine frequency bands around the frequencies f1 to f9 and supplies data [P×J] which represents each frequency band to the gain computing unit 11c. Incidentally, frequency discrimination characteristics of the band pass filter 11a are set based on filter coefficient data prestored in the coefficient table 11b.

The gain computing unit 11c calculates gains of the equalizers EQ₁ to EQ₈ in each frequency band in automatic sound field correction mode based on the data [P×J] representing a level of each frequency band, and supplies calculated gain data [G×J] to the coefficient determining unit 11d. That is, the gain computing unit 11c applies the data [P×J] to a known transfer function of the equalizers EQ₁ to EQ₈, and thereby back-calculates gains of the equalizers EQ₁ to EQ₈ in each frequency band.

The coefficient determining unit 11d generates filter coefficient adjustment signals SF₁ to SF₈ to adjust the frequency characteristics of the equalizers EQ₁ to EQ₈ under control of the system controller MPU shown in FIG. 4 (incidentally, in the case of sound field correction, the filter coefficient adjustment signals SF₁ to SF₈ are generated under conditions specified by the listener).

If the listener does not specify conditions for sound field correction and standard sound field correction preset in the automatic sound field correction system is performed, filter coefficient data for use to adjust the frequency characteristics of the equalizers EQ₁ to EQ₈ is read out of the coefficient table 11e based on the gain data [G×J] specific to frequency bands and supplied from the gain computing unit 11c. Then, the frequency characteristics of the equalizers EQ₁ to EQ₈ are adjusted based on the filter coefficient adjustment signals SF₁ to SF₈ contained in the filter coefficient data.

That is, the coefficient table 11e stores filter coefficient data as lookup tables to adjust the frequency characteristics of the equalizers EQ₁ to EQ₈ in various ways. The coefficient determining unit 11d reads filter coefficient data corresponding to the gain data [G×J] and supplies the filter coefficient data to the equalizers EQ₁ to EQ₈ as the filter coefficient adjustment signals SF₁ to SF₈ to adjust the frequency characteristics on a channel-by-channel basis.

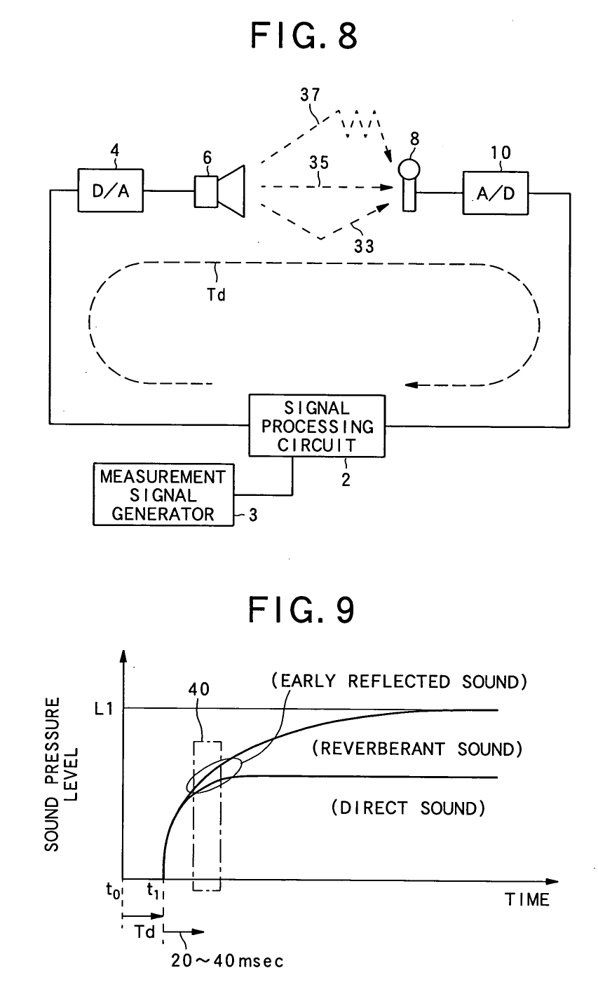

This example is characterized in that the microphone data used by the frequency characteristics correction unit 11 to adjust frequency characteristics does not contain a reverberant component. FIG. 8 schematically shows how the frequency characteristics correction unit 11 adjusts frequency characteristics. As shown in FIG. 8, in the case of frequency characteristics correction, the measurement signal such as pink noise generated by the measurement signal generator 3 is output from the signal processing circuit 2. Then, it goes through the D/A converters 4 and is output from the speakers 6 as measurement signal sounds. The measurement signal sounds are collected by the microphone 8 and supplied as microphone data to the signal processing circuit 2 via the A/D converter 10.

The measurement signal sounds outputted from the speaker 6 reach the microphone 8, being roughly divided into three types of sound: a direct sound component 35, early reflection component 33, and reverberant component 37. The direct sound component 35 is output from the speaker 6 and reaches the microphone 8 directly without being affected by obstacles including walls and floors. Early reflected sound (also referred to as primary reflected sound) component 33 reaches the microphone 8 after being reflected off walls or floors in the room once. The reverberant component 37 reaches the microphone 8 after being reflected off obstacles such as walls and floors in the room a few times.

FIG. 9 shows changes in sound pressure level after a measurement signal sound is output. As the measurement signal sounds, it is assumed that pink noise is output continuously at a constant level. If a measurement signal sound is output at time t0, the measurement signal sound is received by the signal processing circuit 2 at time t1 after a delay time of Td. Incidentally, the delay time Td is a time required for a measurement signal sound outputted from the signal processing circuit 2 to go around a loop shown in FIG. 8 and return to the signal processing circuit 2. Specifically, it is a sum of time required for the measurement signal sound to be sent from the signal processing circuit 2 to the speaker 6 via the D/A converter 4, time required for the measurement signal sound to be transmitted from the speaker 6 to the microphone 8, time required for sound signals collected by the microphone 8 to be sent to the signal processing circuit 2 via the A/D converter 10. In other words, it is a sum of propagation time of the measurement signal sound and time required to electrically process the measurement signal and collected signals.

As shown in FIG. 9, first a direct sound component of the measurement signal sound is received by the signal processing circuit 2 and the direct sound component is also received subsequently at a constant level. Immediately after the time t1 when the direct sound component is received, an early reflection component starts to be received. Then, a few ten msec. after the time t1, a reverberant component increases. Later, the reverberant component saturates at a certain level L1.

According to this example, the measurement signal sound is detected during a period 40 when the direct sound component and early reflection component of the measurement signal sound have reached the signal processing circuit 2 but the reverberant component has hardly arrived (hereinafter this period is referred to as a “direct sound period”) and the frequency characteristics of signal transmission lines for individual channels are adjusted based on results of the detection. This makes it possible to eliminate effects of the reverberant component of the measurement signal sound in frequency characteristics adjustment. The direct sound period 40, which is a period immediately after the measurement signal sound outputted from the speaker reaches the signal processing circuit 2, depends on size and structure of the room or space in which this system is installed. It is known that in a room of a typical house, the direct sound period falls within a range of 20 to 40 msec. after the time t1 when the measurement signal sound is first received. Therefore, the direct sound period can be set to be, for example, a period of approximately 10 msec. within the range of 20 to 40 msec. after the time t1 when the direct sound component of the measurement signal sound is first received. The measurement signal sound can be detected during this period and the detected signal sound can be analyzed to adjust the frequency characteristics.

In this way, by collecting the measurement signal sounds during the direct sound period and adjusting frequency characteristics based on the collected sound data, it is possible to adjust the frequency characteristics of signal transmission lines for individual channels in such a way that target characteristics can be obtained without being adversely affected by the reverberant component. Incidentally, it is preferable to minimize the reverberant component contained in the direct sound period, but some early reflection component may be contained. A reason for this is that when sound source signals are reproduced after the adjustment of frequency characteristics, the user hears not only direct sounds, but also early reflected sounds from floors or walls, and thus it is useful to adjust the frequency characteristics by allowing for the early reflected sounds. Thus, the “direct sound period” may be a period which contains not only the direct sounds of measurement signal sounds, but also early reflected sounds.

Also, as described above, this example has the advantage of being able to make frequency characteristics consistent among different channels even in an environment where reverberation characteristics differ among the different channels as well as the advantage of being able to set target frequency characteristics for direct sounds on a channel-by-channel basis.

Incidentally, several methods are available to actually detect microphone data during a direct sound period. According to one method, the frequency characteristics correction unit 11 shown in FIG. 5A can be configured such that the band pass filter 11a will filter the microphone data DM only during the direct sound period and supply the filtered level data [P×J] to the gain computing unit 11c. According to another method, the band pass filter 11a may perform filtering regardless of periods and the gain computing unit 11c may generate gain data [G×J] based on the level data [P×J] obtained only during the direct sound period.

Next, the channel-to-channel level correction unit 12 will be described. The channel-to-channel level correction unit 12 serves to equalize sound pressure levels of acoustic signals outputted through the channels. Specifically, the microphone data DM obtained when the speakers 6_{FL} to 6_{SBR} are sounded by the measurement signal (pink noise) DN outputted from the measurement signal generator 3 are input in sequence and levels of sounds reproduced by the speakers at the listening position RV are measured based on the microphone data DM.

A configuration of the channel-to-channel level correction unit 12 is outlined in FIG. 5B. The microphone data DM outputted from the A/D converter 10 is input in a level detection unit 12a. Incidentally, the channel-to-channel level correction unit 12 attenuates levels uniformly over an entire bandwidth of channel signals, eliminating the need to divide bands, and thus does not contain a band pass filter such as the one contained in the frequency characteristics correction unit 11 shown in FIG. 5A

The level detection unit 12a detects levels of the microphone data DM and adjusts gains to make output audio signal levels of different channels uniform. Specifically, the level detection unit 12a generates amounts of level adjustment which represent differences between the detected levels of the microphone data and a reference level and outputs them to an adjustment determining unit 12b. The adjustment determining unit 12b generates gain adjustment signals SG₁ to SG₈ which correspond to the amounts of level adjustment received from the level detection unit 12a and supplies them to the channel-to-channel attenuators ATG₁ to ATG₈. The channel-to-channel attenuators ATG₁ to ATG₈ adjust the attenuation factors of audio signals of individual channels according to the gain adjustment signals SG₁ to SG₈. In this way, the channel-to-channel level correction unit 12 adjusts the attenuation factors, making level adjustments (gain adjustment) among the channels and making the output audio signal levels of different channels uniform.

The delay characteristics correction unit 13 serves to adjust signal delays caused by range differences between speaker locations and the listening position RV and prevent output signals from the different speakers 6 which should reach the listener simultaneously from arriving at the listening position RV at different times. Thus, the delay characteristics correction unit 13 measures delay characteristics of the individual channels based on the microphone data DM obtained when the speakers 6 are sounded by the measurement signal (pink noise) DN outputted from the measurement signal generator 3 and corrects phase characteristics of the audio space based on results of the measurement.

Specifically, as switches SW₁₁ to SW₈₂ shown in FIG. 3 are operated in sequence, the measurement signal DN generated by the measurement signal generator 3 is output from each speaker 6 on a channel-by-channel basis. The speaker outputs are collected by the microphone 8 and corresponding microphone data DM are generated. If the measurement signal is a pulsed signal such as impulses, difference between time when the pulsed measurement signal is output from a speaker 6 and time when a corresponding pulse signal is received by the microphone 8 is proportional to distance between the speaker 6 and microphone 8. By adding together the largest of the measured delay time and the delay times on the other channels, it is possible to smooth out the differences in the distance between speaker 6 and listening position RV among different channels. This makes it possible to equalize signal delays among the speakers 6 on different channels. Consequently, sounds which are produced by the different speakers 6 and coincide with each other on a time axis reach the listening position RV simultaneously.

FIG. 5C shows a configuration of the delay characteristics correction unit. A delay calculation unit 13a receives the microphone data DM and calculates an amount of signal delay in a sound field environment on a channel-by-channel basis based on an amount of pulse delay between the pulsed measurement signal and microphone data. A delay determining unit 13b receives the amount of signal delay on each channel from the delay calculation unit 13a and stores it temporarily in a memory 13c. When the amounts of signal delays on all the channels are stored in the memory 13c, the delay determining unit 13b determines the amount of adjustment for each channel in such a way that a reproduced signal on the channel with the largest amount of signal delay will reach the listening position RV simultaneously with reproduced signals on the other channels and supplies adjustment signals SDL₁ to SDL₈ to the delay circuits DLY₁ to DLY₈ of the channels. The delay circuits DLY₁ to DLY₈ adjust the amounts of delays based on the adjustment signals SDL₁ to SDL₈. In this way, the delay characteristics of individual channels are adjusted. Incidentally, although a pulsed signal is used as the measurement signal for delay adjustment in the above example, this is not restrictive and other types of measurement signal may be used.

2. Automatic Sound Field Correction Process

Next, description will be given of automatic sound field correction operation of the automatic sound field correction system with the above configuration.

In an operating environment of the audio system 100, for example, the listener places the speakers 6_{FL} to 6_{SBR} in the listening room 7 as shown in FIG. 6 and connects them to the audio system 100 as shown in FIG. 1. Then, as the listener starts automatic sound field correction using a remote control (not shown) or the like provided for the audio system 100, the system controller MPU performs automatic sound field correction in response.

Next, a basic principle of the automatic sound field correction according to the present invention will be described. As described earlier, the automatic sound field correction includes processes of frequency characteristics correction, sound pressure level correction, and delay characteristics correction for individual channels. The present invention is characterized in that frequency characteristics correction involves adjusting the frequency characteristics of individual channels mainly in relation to direct sounds (including early reflected sounds) so that desired frequency characteristics can be obtained.

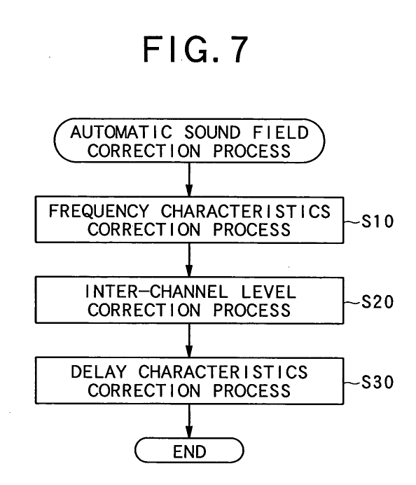

Next, an automatic sound field correction process including the frequency characteristics correction will be described with reference to a flowchart in FIG. 7.

First, in Step S10, the frequency characteristics correction unit 11 adjusts the frequency characteristics of the equalizers EQ₁ to EQ₈. Next, in a channel-to-channel level correction process in Step S20, the channel-to-channel level correction unit 12 adjusts the attenuation factors of the channel-to-channel attenuators ATG₁ to ATG₈ installed on individual channels. Then, in a delay characteristics correction process in Step S30, the delay characteristics correction unit 13 adjusts the delay times of the delay circuits DLY₁ to DLY₈ on all the circuits. The automatic sound field correction according to the present invention is performed in this order.

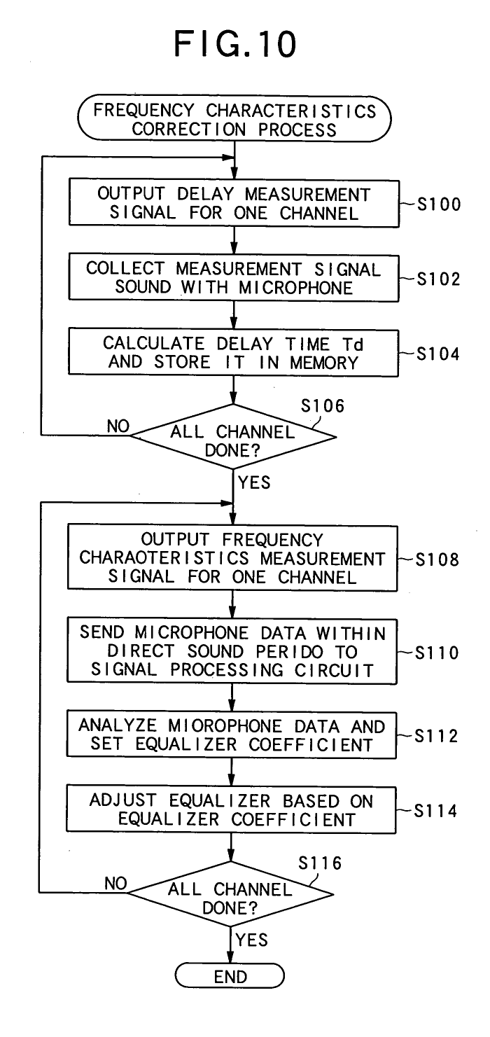

Next, operations of processing steps will be described in detail. First, the frequency characteristics correction process in Step S10 will be described with reference to FIG. 10. FIG. 10 is a flowchart of the frequency characteristics correction process according to this example. Incidentally, the frequency characteristics correction process in FIG. 10 is performed to measure delays on individual channels prior to the frequency characteristics correction process of the individual channels. The delay measurement here consists in measuring the delay between the time when the signal processing circuit 2 outputs the measurement signal and the time when the corresponding microphone data reaches the signal processing circuit 2, i.e., measuring the delay time Td in FIG. 8 on a channel-by-channel basis in advance. As shown in FIG. 9, since the direct sound period 40 falls within a predetermined time range counting from the time t1 when a measurement signal sound reaches the signal processing circuit 2, if the delay time Td is measured on a channel-by-channel basis, the signal processing circuit 2 can tell the time t1 accurately and detect the microphone data DM within the direct sound period 40 accurately. In FIG. 10, Steps S100 to S106 correspond to the delay measurement process while Steps S108 to S116 correspond to the actual frequency characteristics correction process.

Referring to FIG. 10, the signal processing circuit 2 outputs, for example, a pulsed delay measurement signal for one of the channels and this signal is output through the speaker 6 as a measurement signal sound (Step S100). The measurement signal sound is collected by the microphone 8 and the microphone data DM is supplied to the signal processing circuit 2 (Step S102). The frequency characteristics correction unit 11 in the signal processing circuit 2 calculates the delay time Td and stores it in an internal memory or the like (Step S104). When the processes in Steps S100 to S104 are repeated for all the channels (Step S106: Yes), the delay times Td on all the channels are stored in the memory. This completes the measurement of delay times.

Next, frequency characteristics correction is performed on each channel. Specifically, the signal processing circuit 2 outputs frequency characteristics measurement signal such as pink noise for one of the channels and this signal is output through the speaker 6 as a measurement signal sound (Step S108). The measurement signal sound is collected by the microphone 8 and only the microphone data within the direct sound period is acquired by the frequency characteristics correction unit 11 of the signal processing circuit 2 using the method illustrated above (Step S110). Then, the gain computing unit 11c of the frequency characteristics correction unit 11 analyzes the microphone data, the coefficient determining unit 11d sets an equalizer coefficient (Step S112), and the equalizer is adjusted based on the equalizer coefficient (Step S114). This completes the adjustment of the frequency characteristics for one channel based on the microphone data acquired during the direct sound period. This process is repeated for all the channels (Step S116: Yes) to complete the frequency characteristics correction process.

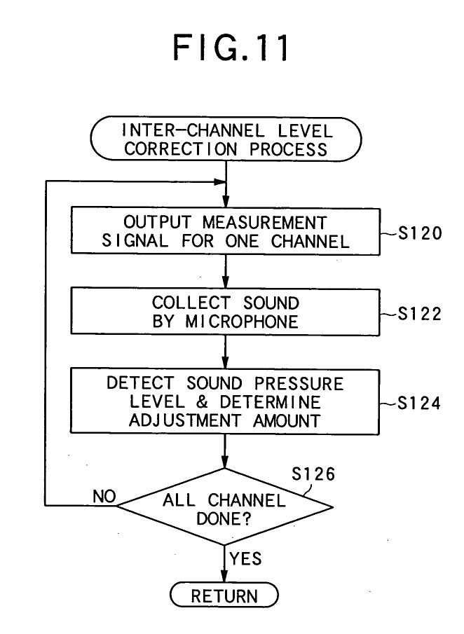

Next, the channel-to-channel level correction process in Step S20 is performed. It is performed according to a flowchart shown in FIG. 11. Incidentally, the channel-to-channel level correction process is performed with the frequency characteristics of the graphic equalizer GEQ, which is set by the previous frequency characteristics correction process, kept in adjustment after the frequency characteristics correction process.

In the signal processing unit 20 shown in FIG. 3, when the switch SW₁₁ is turned on and the switch SW₁ is turned off, the measurement signal (pink noise) DN is supplied to one channel (e.g., the FL channel) and outputted from the speaker 6_{FL} (Step S120). The microphone 8 collects the signal and supplies the microphone data DM to the channel-to-channel level correction unit 12 in the coefficient computing unit 30 via the amplifier 9 and the A/D converter 10 (Step S122). In the channel-to-channel level correction unit 12, the level detection unit 12a detects the sound pressure level of the microphone data DM and sends it to the adjustment determining unit 12b. The adjustment determining unit 12b generates an adjustment signal SG₁ for the channel-to-channel attenuator ATG₁ in such a way as to match a predetermined sound pressure level stored in a target table 12c and supplies it to the channel-to-channel attenuator ATG₁ (Step S124). In this way, the level of one channel is adjusted to match the predetermined level. This process is repeated for every channel in sequence and when level corrections of all the channels are completed (Step S126: Yes), processing returns to a main routine in FIG. 7.

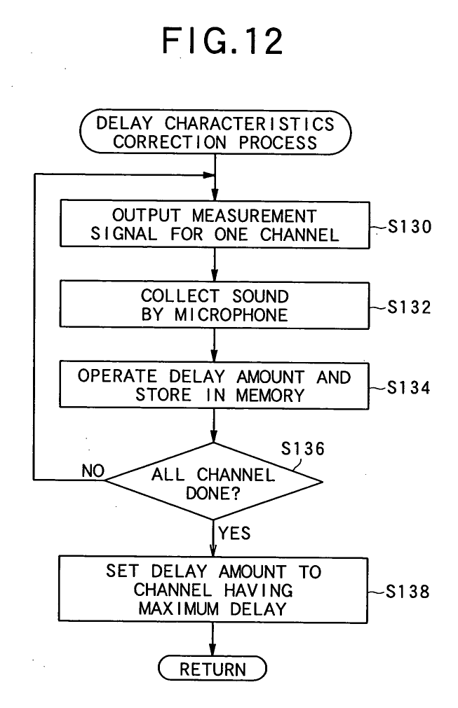

Next, the delay characteristics correction process in Step S30 is performed according to a flowchart shown in FIG. 12. When the switch SW₁₁ is turned on and the switch SW₁₂ is turned off for one channel (e.g., the FL channel), the measurement signal DN is output from the speaker 6 (Step S130). The outputted measurement signal DN is collected by the microphone and the microphone data DM is input in the delay characteristics correction unit 13 of the coefficient computing unit 30 (Step S132). In the delay characteristics correction unit 13, the delay calculation unit 13a calculates the amount of delay for the given channel and stores it temporarily in the memory 13c (Step S134). This process is repeated for all the other channels. When the processing of all the channels is completed (Step S136: Yes), the amounts of delays on all the channels are stored in the memory 13c. Then, the delay determining unit 13b determines coefficients for the delay circuits DLY₁ to DLY₈ of the respective channels based on contents of the memory 13c so that the signal on the channel with the largest amount of delay will reach the listening position RV simultaneously with the signals on the other channels and supplies the coefficients to the delay circuits DLY (Step S138). This completes the delay characteristics correction.

In this way, the frequency characteristics, channel-to-channel levels, and delay characteristics are corrected to complete the automatic sound field correction.

3. Variations

In the frequency characteristics correction process shown in FIG. 10, the delay times Td are measured in advance on a channel-by-channel basis to allow the signal processing circuit 2 to tell the direct sound period accurately. In a system which can tolerate some error, a predetermined delay time may be applied to all or part of the channels instead of measuring delays on a channel-by-channel basis. For example, since there is generally no significant difference in distance from the microphone 8 to the speakers 6 among household systems or the like, a standard delay time may be used by determining it experimentally in living rooms of a standard size in advance. Alternatively, it is possible to allow the user to select between a mode in which frequency characteristics are corrected using a delay time prepared in advance in such a manner and a mode in which frequency characteristics are corrected by taking delay measurements as in the case of the above example.

Although in the above embodiment, the signal processing according to the present invention is performed by a signal processing circuit, the same signal processing may be implemented by a program which runs on a computer. In that case, the program is supplied on a recording medium such as a CD-ROM or DVD or via network-based communications. The computer may be a personal computer connected with peripheral devices including an audio interface which supports multiple channels, a plurality of speakers, and a microphone. By running the program on the personal computer, it is possible to generate a measurement signal using a sound source provided inside or outside the computer, output the measurement signal via the audio interface and speaker, and collect it with the microphone. In short, it is possible to implement an automatic sound field correction apparatus such as the one shown in FIG. 1 using the computer.

The present invention has been described in detail by way of illustrations, embodiments and examples for purposes of clarity and understanding. However, it will be obvious that the present invention is not limited to the embodiments, or examples described herein, and that certain changes and modifications may be practiced within the scope of the invention, as limited only by the scope of the appended claims.

The entire disclosure of Japanese Patent Application No. 2003-209056 filed on Aug. 27, 2003, including specification, claims, drawings and summary are incorporated herein by reference in its entirety.

1. An automatic sound field correction apparatus which processes a plurality of audio signals on respective signal transmission lines and outputs the audio signals to respective speakers, comprising:
equalizers which adjust frequency characteristics of the audio signals on the signal transmission lines;
a measurement signal supply device which supplies a measurement signal to the signal transmission lines;
a detection device which outputs measurement signal sounds emitted from the speakers, as detection signals during a direct sound period; and
a gain determination device which determines equalizer gain values for use by the equalizers to adjust the frequency characteristics, based on the detection signals, and supplies them to the equalizers,
wherein the direct sound period is a period during which the measurement signal sounds reaching the detection device do not contain a reverberant component.

2. The automatic sound field correction apparatus according to claim 1, wherein the direct sound period is a period during which the measurement signal sounds reaching the detection device contain a direct sound component and early reflection component.

3. The automatic sound field correction apparatus according to claim 1, wherein the direct sound period falls within a predetermined time range counting from a time point at which a measurement signal sound is first detected by the detection device.

4. The automatic sound field correction apparatus according to claim 3, wherein the predetermined time range is 20 to 40 msec.

5. The automatic sound field correction apparatus according to claim 3, further comprising:
a delay measuring device which measures signal delay times on the respective signal transmission lines; and
wherein the detection device determines the direct sound period based on the time point at which the measurement signal sounds are emitted from the speakers, the signal delay times on the signal transmission lines, and the predetermined time range.

6. A computer program for making a computer function as an automatic sound field correction apparatus which processes a plurality of audio signals on respective signal transmission lines and outputs the audio signals to respective speakers, the automatic sound field correction apparatus comprising:
equalizers which adjust frequency characteristics of the audio signals on the signal transmission lines;
a measurement signal supply device which supplies a measurement signal to the signal transmission lines;
a detection device which outputs measurement signal sounds emitted from the speakers, as detection signals during a direct sound period; and
a gain determination device which determines equalizer gain values for use by the equalizers to adjust the frequency characteristics, based on the detection signals, and supplies them to the equalizers,
wherein the direct sound period is a period during which the measurement signal sounds reaching the collection device do not contain a reverberant component.
